(19) United States
(12) Patent Application Publication
(10) Pub. No.: US 2005/0087221 A1
(43) Pub. Date: Apr. 28, 2005

(54) Heat conversion system

(76) Inventor: Reza H. Shah, Acton (CA)

Correspondence Address: DAVID W. WONG, 46 WILLOWBROOK ROAD, THORNHILL, ON, L3T 4W9, CA

(21) Appl. No.: 10/694,222

(22) Filed: Oct. 28, 2003

(51) Int. Cl. H01L 35/30; H01L 35/28

(52) U.S. Cl. 136/205

(57) ABSTRACT

An energy conversion system is provided for converting heat energy from a variety of heat sources to electric power for operating electrical appliances. The system may be incorporated in a power on demand pilot system of a gas operated equipment to provide the sole electric power for operating the equipment. Thermoelectric modules provide the basic transducer for converting the heat energy to electric power and a heat pipe is employed for conducting the heat energy from a heat source to the conversion system.

### FIELD OF THE INVENTION

This invention relates to systems for converting heat energy to electric and/or mechanical power. More particularly, it relates to systems for utilizing heat energy from various sources to provide the electric power for operating the electrical components such as the blower fan in a heating, cooling, and venting equipment or other electrical appliances.

### BACKGROUND OF THE INVENTION

The main components of heating, cooling and venting equipment nowadays all totally dependent on electric power to operate. Particularly, the blower fan and/or the compressor in such equipment consume a large amount of electrical energy, since their operating duty cycle between the ON period and the OFF period may be from a few minutes to up to several hours. Even for an oil or natural gas operated heating furnace, it still requires electrical power to operate and to sustain their electrically operated fuel injector and ignition coil. In cold climate regions, the furnace is particularly essential in the winter time for heating the house to a habitable environment. In the event of any electric power stoppage or failure which renders such essential equipment ceasing to function; it would cause potentially not only property and other damages but also detriment to human life. Emergency electricity generators or standby batteries may be provided to safeguard the occurrence of such event, but back up devices are expensive to install and operate. Therefore, they are not desirable for a common household to acquire. Furthermore, they are for emergency use only, and they may not be incorporated into the heating, cooling and venting equipment as an integral component for the normal operation of these equipment which can also provide the advantage of reducing their electric power consumption.

The present invention alleviates the above problem by providing heat to electric power conversion systems to provide the electrical power required for operating the heating, cooling and venting equipment. The system operates by power on demand particularly for a natural gas furnace so that a continuously operating heat source is not required. Thus it can also significantly reduce the electric as well as gas fuel consumption of the equipment. In remote locations where it is not feasible to use oil or natural gas to provide the heat source; wood, or other naturally available fuel material may be used to provide the heat source to generate the required electric power. Solar heat, wind, tidal waves and other energy source can also be converted to electric power by the system of the present invention.

### SUMMARY OF THE INVENTION

It is the principal object of the present invention to provide an energy conversion system for converting heat energy to electric power.

It is another object of the present invention to provide an energy conversion system which converts heat energy from a large variety of different heat sources to electric power for operating the heating, cooling and venting equipment.

It is another object of the present invention to provide an energy conversion system which may be incorporated in a gas or oil operated heating and cooling equipment for alleviating their external electric power dependency.

It is another object of the present invention to provide an energy conversion system which may be incorporated as an integral component in a heating, cooling, and venting equipment for reducing their electric power and fuel consumption in their normal operation.

It is another object of the present invention to provide an energy conversion system operating with a high efficiency.

It is yet another object of the present invention to provide an energy conversion system which is economically feasible for incorporating into a general household heating, cooling and venting equipment.

It is still another object of the present invention to provide an energy conversion system which is easy to manufacture and reliable in operation.

### BRIEF DESCRIPTION OF THE DRAWINGS

In the drawings,

FIG. 1 is a schematic diagram of a unit thermoelectric module which may be used as a basic transducer in the system of the present invention for the energy conversion.

FIG. 2 is a schematic diagram of a thermopile consisting of a plurality of the thermoelectric modules of that of FIG. 1 linked together to provide a desirable level of electrical voltage output.

FIG. 3 is a perspective partial cross sectional elevation view of a heat pipe with a portion of its outer casing removed to show its internal construction. Such heat pipe is effective for delivering heat from a heat source to the transducer of the present invention for converting heat energy to electric power.

FIG. 4 is a side cross sectional elevation view of the heat pipe of FIG. 3 showing the menisci in the wick lining therein.

FIG. 5 is a partially perspective schematic diagram of the pilot light on demand system of a heating furnace for the conversion system of the present invention.

FIG. 6 is a schematic circuit diagram of the system shown in FIG. 5 having a thermopile according to the present invention for converting heat energy to electric power for operating the natural gas heating furnace.

FIG. 7 is a schematic diagram showing an embodiment of the present system having a thermopile according to the present invention for converting heat from a natural gas heat source to electric power.

FIG. 8 is a schematic diagram showing an embodiment of the system of the present invention having a heat pipe for conveying the heat energy from a wood fire heat source to the system for converting it to electric power.

FIG. 9 is a schematic diagram showing a conversion system according to the present invention for converting heat energy to dual mechanical and electrical energies.

FIG. 10 is a schematic diagram of a digital control for the conversion system of the present invention for increasing the load capacity of the system.

FIG. 11 is a schematic block diagram of the system according to the present invention for operating a heating equipment in the heat cycle.

FIG. 12 is a schematic block diagram of the system according to the present invention for operating a cooling system in the cool cycle.

### DETAILED DESCRIPTION OF THE PREFERRED EMBODIMENTS

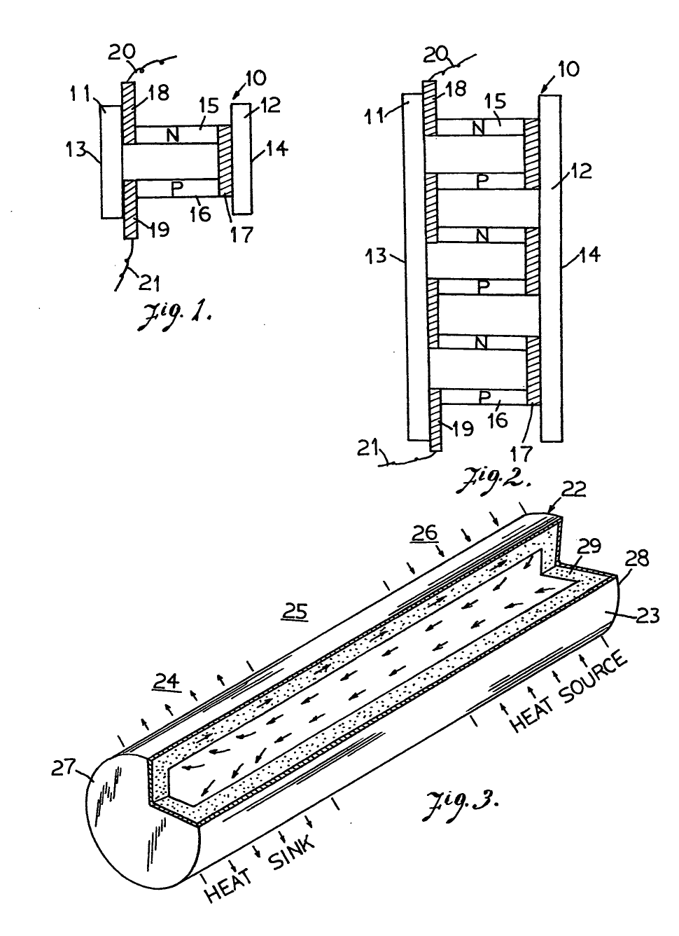

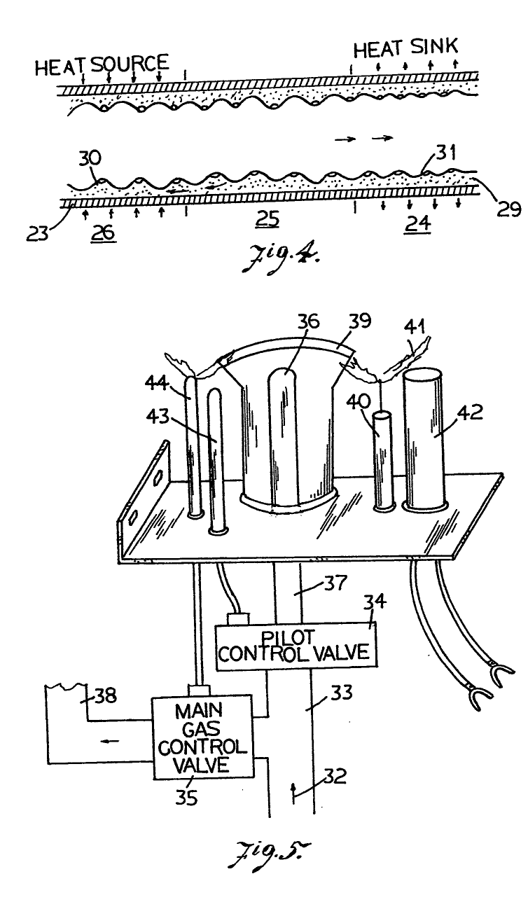

The conversion system of the present invention employs a thermopile as a basic transducer to derive the electric power required for operating electrical appliances such as the heating, cooling and venting equipment. The operation of the thermopile system may be accomplished by receiving the heat energy provided by an operate-on-demand pilot arrangement. A thermopile consists of a plurality of thermoelectric modules connected together. The construction of a thermoelectric module 10 is best shown in FIG. 1. The thermoelectric module 10 consists of two heat conductive electrical insulator blocks 11 and 12 having outer surfaces 13 and 14 respectively. The external surface 13 of the insulator block 11 is the hot junction of the module, while the external surface 14 of the insulator block 12 is the cold junction. Two spaced parallel different types of semiconductor elements 15 and 16 are located between the insulator blocks 11 and 12. Element 15 is an N-type semiconductor and element 16 is a P-type semiconductor or vice versa. One end of the semiconductor blocks 15 and 16 is electrically and commonly connected to one another by an electrical conductor 17 which abuts the inner surface of the insulator block 14 at the cold junction. The other end of the N-type semiconductor block 15 is electrically connected to an electrical conductor 18 which contacts the inner surface of the insulator block 13 at the hot junction, while the other end of the P-type semiconductor block 16 is electrically connected to an electrical conductor 19 which also contacts the inner surface of the insulator block 13 at the hot junction. When heat is applied to the external surface 13 of the hot junction of the module, it creates a temperature differential between the two junctions so that an electrical voltage is inherently generated between them due to thermoelectric action. Current from this voltage can be delivered to a resistive load through electrical conducting wires 20 and 21 connected to the electrical conductors 18 and 19 respectively. When power is drawn from this module, it would cause the heated junction to cool down intrinsically while the cold junction would heat up intrinsically. The higher the amount of current is drawn from the module, the greater is this effect which, in turn, increases the transfer of heat from the hot junction to the cold junction. The present invention utilizes this effect to enhance the heat transfer; this is achieved by increasing the current load at low voltage level or maintaining it at a maximum value permitted by the device's specified limit and decreasing the current load at higher voltages where the transfer is already high and the power in the device is high. MOSFET devices having a very low ON resistance can be employed to provide this operation. A plurality of the thermoelectric module 10 may be connected in series to form a thermopile as best shown in FIG. 2 to provide a total output voltage of a desirable level.

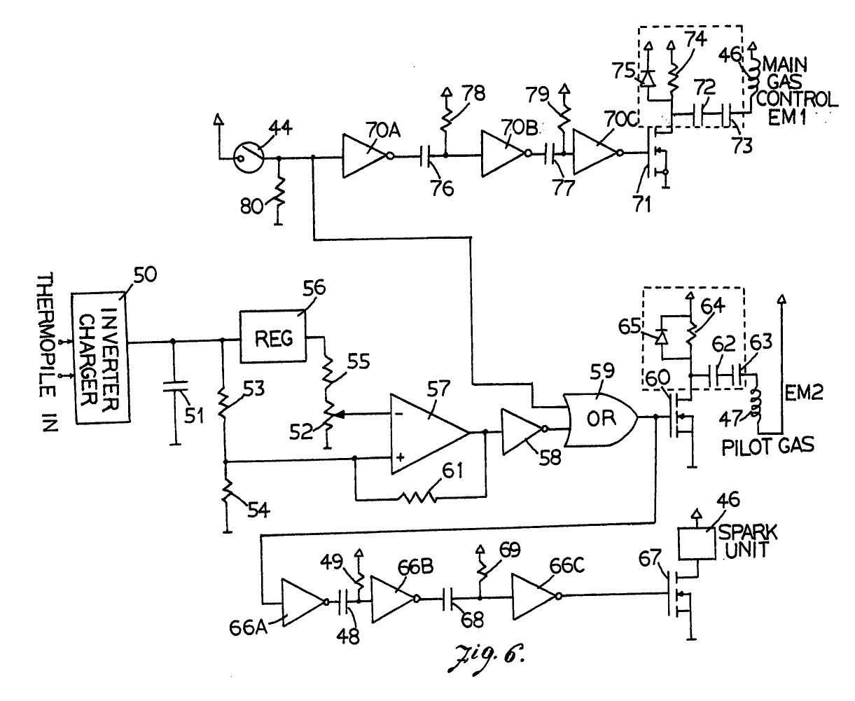

A heat pipe is employed for obtaining the heat energy with high efficiency from a heat source in a spaced location in the present conversion system. The construction and operation of a heat pipe is best shown in FIGS. 3 and 4. The heat pipe 22 has a completely sealed cylindrical outer casing 23 and it is functionally divided into three sections, namely, a condenser section 24 at one end, an adiabatic section 25 in the middle, and an evaporator section 26 at the other end. The cylindrical outer casing 23 is sealed by two end caps 27 and 28. A fluid absorbent wick-like material 29 lines the entire inner surface of the cylindrical outer casing 23 as well as the end caps 27 and 28. A small amount of fluid which is in equilibrium with its own vapor is located in the cavity as well as the wick-like lining 29. When heat is applied to the evaporator section 26 of the casing 23, the heat causes the fluid in the lining 29 in that section to vaporize; the resulting vapor pressure generated due to the vaporization drives the vapor to flow through the adiabatic section 25 to the cooler condenser section 24 in the other end portion. The vapor condenses and returns to the fluid state by releasing its latent heat to the outer casing 23 at the condenser section 24 which functions as a heat sink. The capillary pressure created by the menisci in the wick-like lining 29 pumps the condensed fluid back to the evaporator section 26. In this manner, the heat pipe 22 continues to transport the latent heat of vaporization from the evaporator section 26 to the condenser section 24 with a high efficiency. This process will continue as long as there is sufficient capillary pressure in the wick-line lining 29 to drive the condensate back to the evaporator. As best shown in FIG. 4, the menisci 30 in the liquid vapor interface are highly curved in the evaporator section 26 due to the fact that the liquid recedes into the pores of the wick-like material lining 29. On the other hand, during the condensation process the menisci 31 in the condenser section 24 are nearly flat. A capillary pressure exists at the liquid-vapor interface due to the surface tension of the working fluid and the curved structure of the interface. The difference in the curvature of the menisci along the liquid-vapor interface causes the capillary pressure to change along the length of the heat pipe. This capillary pressure gradient circulates the fluid against the liquid and vapor pressure losses, and adverse body forces such as gravity due to the physical positioning of the heat pipe.

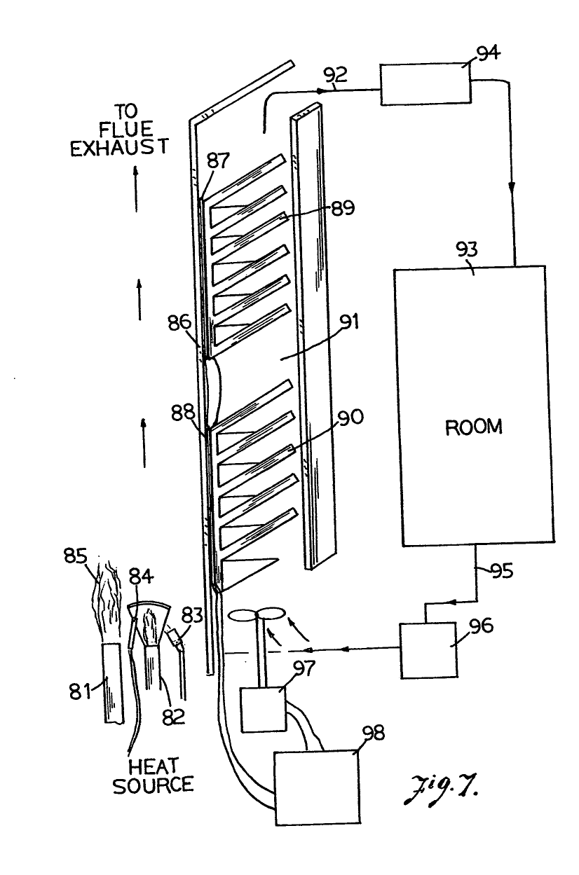

For a heating furnace, the present system provides separate controls for the gas supplied to the pilot and the main burner such that the pilot burner operates only on demand. This control arrangement is best shown in FIG. 5. The gas 32 is conducted by a supply pipe 33 to both the pilot control valve 34 and main gas control valve 35; and the gas from the pilot control valve 34 is conveyed to the pilot burner 36 through the conducting pipe 37. The gas is directed to the main burner from the main gas control valve 35 by outlet conducting pipe 38. A hood 39 is provided on the pilot burner 36 to direct the gas to be ignited by the spark generator unit 40 so that the pilot flame 41 would provide the heat energy for the thermopile 42. The hood 39 also directs the flame to the pilot control thermostat sensor 43 and the main gas control thermostat sensor 44 located adjacent to the pilot burner 36. As best shown in FIG. 6, the main gas control valve 35 and the pilot control valve 34 are schematically shown by coils 46 and 47 respectively which are fast acting and very low current momentary electromagnetic valves EM1 and EM2. Gas is allowed to flow to the pilot burner 36 whenever the command to ignite the pilot is actuated. The capacitor 48 in combination with a resistor 49 provides a predetermined delay period for igniting the spark generator unit 40 soon after the ignition command is actuated. The electric power to operate the pilot control valve 34, the main gas control valve 35, and the ignition of the spark generator 40 as well as the electronic control circuit is provided by the thermopile 42. The pilot flame 41 is turned on in predetermined intervals in every few hours for a period of a few minutes or as the situation demands. The DC voltage generated by the thermopile 42 is increased to a higher voltage level by an inverter charger 50. This higher voltage charges a super capacitor 51 which is capable of holding a large charge voltage for up to a few hours. When the voltage of the super capacitor 51 reaches a predetermined amount of voltage level set by the potentiometer 52 in conjunction with resistors 53, 54, 55 and regulator 56, the command to turn off the pilot flame 41 is actuated to the pilot control valve 34 through amplifier 57, inverter 58, OR gate 59 and transistor 60. The resistor 61 is connected across the amplifier 57 to provide some hysteresis for a positive feedback. When the voltage of the super capacitor 51 falls below a predetermined voltage level, the pilot flame 41 is turned on again thus maintaining the super capacitor 51 charged at all time for operating all the electrical components including the control electronic circuit, the control valves 34 and 35, and the spark generator unit 40. The OR gate 59 serves to turn on the pilot flame 41 whenever it is required either to ignite the main burner or to supply the heat to operate the thermopile 42 for charging the super capacitor 51. When the thermostat of the pilot control valve 34 closes, it first operates the pilot gas electromagnetic EM2 by turning on the transistor 60. The thermopile 42, the pilot control thermostat sensor 43, and the main gas control thermostat sensor 44 may be replaced by one or two thermopile or a single thermocouple for connecting in series or parallel to the electromagnet valves EM1 and EM2 respectively. The capacitors 62 and 63 are charged slowly by a high value resistor 64 in combination with a diode 65 connected in parallel therewith. When the transistor 60 is turned on, it provides a pulse to operate the electromagnetic valve EM2 so that gas would flow to the pilot burner 36 for ignition by the spark generator unit 40 which is turned on through the cascade of inverters 66A, 66B, 66C and transistor 67. Capacitor 68 is connected between inverters 66B and 66C, and resistor 69 connects the inverter 66C to the voltage supply. The pilot gas control circuit is designed to safeguard the potential hazard of any two components in the system from accidentally becoming open circuited or short circuited so that gas will not be allowed to flow continuously to the burners. The same safety circuit is provided to the operation of the electromagnetic valve EM1 of the main gas control valve 35 by the cascade of inverters 70A, 70B, and 70C and the transistor 71 in conjunction with capacitors 72 and 73 which are charged by a resistor 74 having a diode 75 connected in parallel therewith. The thermostat 44 of the main gas control valve 35 is connected to the voltage supply through a resistor 80. After the demand for gas is actuated for the main burner of the furnace, the gas flow is delayed for a predetermined period set by the resistor 78 in combination with a capacitors 76 in order to allow a time period for the pilot flame 41 to heat up the thermopile 27 so as to provide the signal to open the electromagnetic valve EM1 of the main gas control valve 35. A capacitor 77 and a resistor 79 in combination also provide the same delay control for the inverter 70C.

The detection of voltage level in the super capacitor 51 is provided by comparing its voltage divided by resistors 53 and 54 to a reference voltage obtained via the regulator 56, the resistor 55 and the potentiometer 52. In this manner, the super capacitor 51 is maintained charged at all time.

It can be appreciated that the control system of the present invention may be incorporated into the normal operating control to eliminate the continuous operation of one or more standing pilot in any gas operated appliance.

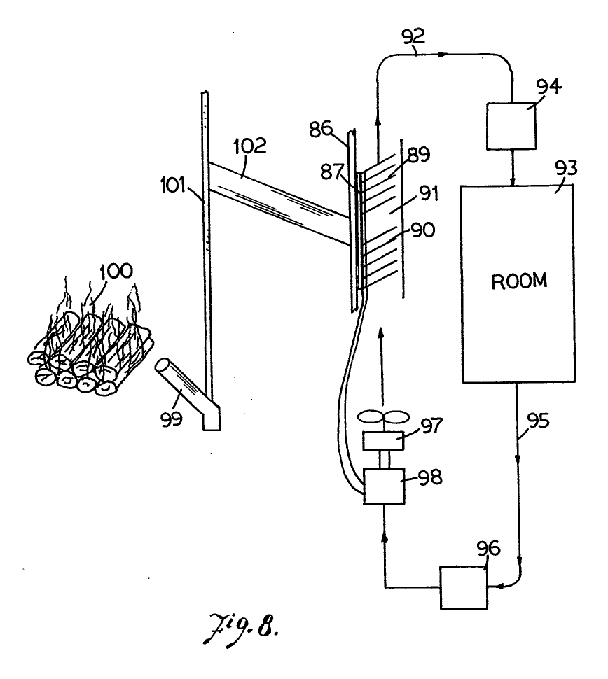

The conversion system of the present invention may be employed for providing the electric power from a gas combustion heat source as best shown in FIG. 7. The heat source may alternatively be obtained from solar, firewood, or waste energy from an industrial plant. As shown in FIG. 7, the gas equipment has the common components, namely, a main burner 81, a pilot burner 82 which operates on demand, a spark generator 83 operative to ignite the pilot burner 82, and a thermostat sensor 84 located adjacent to the pilot burner 82 for controlling the operation of the latter. The flame 85 heats up the combustion chamber which has a vertical heat conducting side wall 86. A plurality of thermoelectric modules are attached to the opposite surface of the side wall 86 such as by thermally conductive but electrically insulated adhesive material applied on this surface so as to provide a good thermal contact between the wall 86 and the thermoelectric modules. For simplicity of illustration, two thermoelectric modules 87 and 88 are shown in FIG. 7 as an example. The thermoelectric modules 87 and 88 are connected in series or alternatively in parallel for deriving the required amount of electric power. Heat sinks 89 and 90 are attached to the thermoelectric modules 87 and 88 respectively and are located in the cavity 91 of a heat exchange chamber for extracting the maximum amount of heat energy from the combustion heat source. In the example illustrated, the vertical heat conducting wall 86 is heated by the burner flame 85. The heat is conducted by the conducting wall 86 to the thermoelectric modules 87 and 88. The warm air is conveyed into the room 93 to be heated through a hot air vent 94. The cooler air 95 from the room 93 is directed by the cold air return vent 96 by a blower fan 97 to circulate through the heat exchange cavity 91 to be heated by the heat sinks 89 and 90 before returning to the room 93. The electric power for operating the controls of the main burner, the pilot burner, the spark generator is provided with the system of the present invention shown as block 98 in FIG. 7.

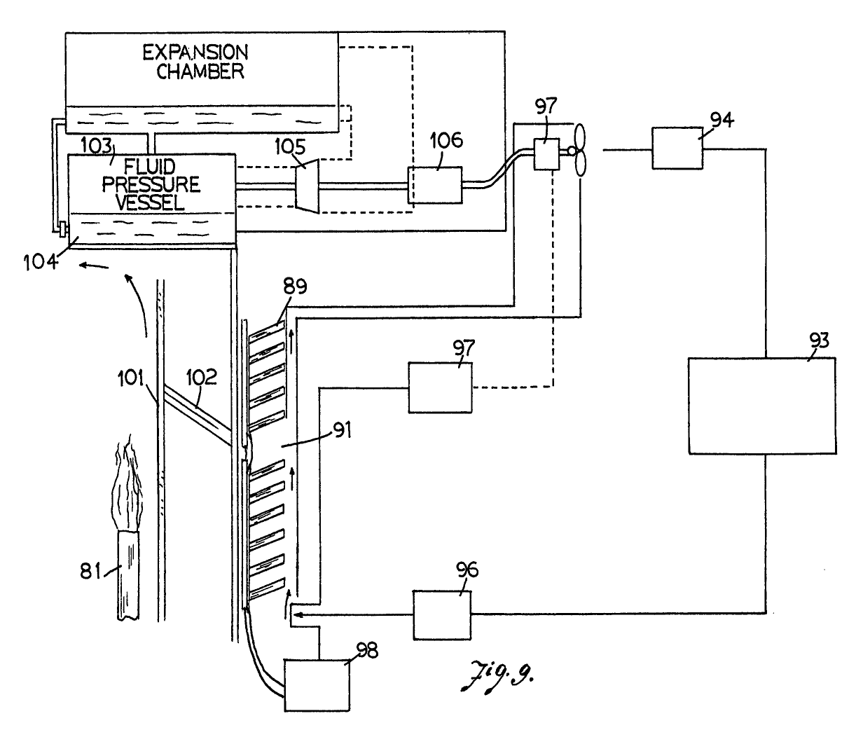

When the heat source is provided by other means such as a wood fire the electric power may be derived by a different method as illustrated in FIG. 8. In this embodiment, the thermopile 99 may be located directly at the wood fire 100 such as that of a fireplace for deriving the electric voltage input to the conversion system as shown in FIG. 6 for obtaining the electric power. Alternatively, the flue wall 101 of the fireplace may having a metallic construction such that it would be heated by the flame in the fireplace. A heat pipe 102 is attached between the flue wall 101 and the heat exchange chamber side wall 86 spaced from the flue wall 101. The heat pipe 102 conducts the heat from the flue wall 101 to the heat exchange chamber side wall 86 with high efficiency as described above. The heat in the heat exchange chamber is circulated through the room 93 to be heated similar to that shown in FIG. 7, and the conversion system of the present invention is provided as schematically shown by the block 98 for supplying the electric power required.

As shown in FIG. 9, the conversion system of the present invention may be used for converting the heat energy from other energy sources such as solar heat, hot spring, or volcanic pool, etc., which is schematically illustrated as a burner 81, the heat from the heat source is used to heat a pressure vessel 103. A fluid 104, having a low boiling point similar to the fluid in an air conditioning system, is contained within the pressure vessel 103. When the fluid 104 is heated, it creates a high pressure gas in the cavity of the pressure vessel 103. The pressure gas is directed to a turbine or piston heat engine 105 which drives the electric generator 106 to produce the required electric power. The heat source may also provide the heat energy for heating a flue wall 101 and the heat from the flue wall 101 is conducted in turn to the heat exchange chamber wall by a heat pipe similar to that shown in FIG. 8 for providing the hot air to heat a room 93 and to circulate therethrough. Electric power may be derived from the conversion system located in block 98 and combined with that generated by the generator 106 to provide the required electric power. The circulation fan 97 may be driven by the generated power or alternatively by the mechanical motion of the turbine shaft through a sealed bearing.

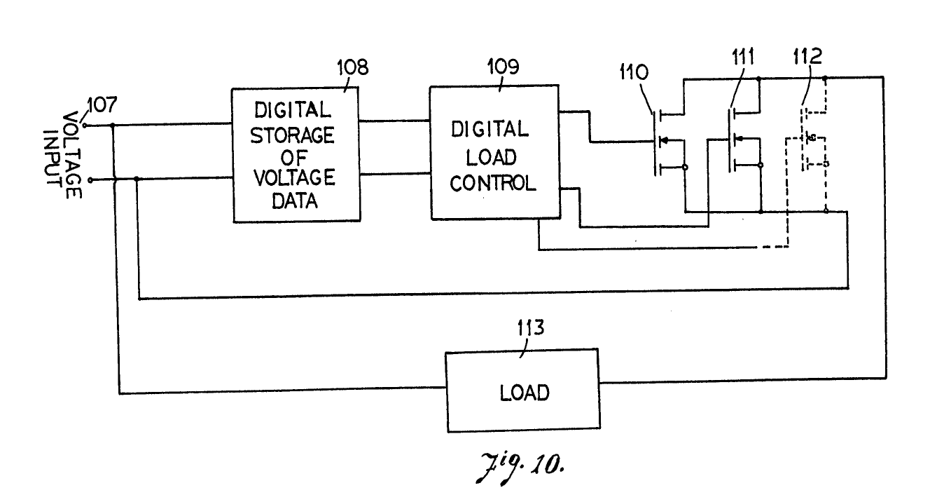

The load operated by the electric power derived from the conversion system of the present invention may be controlled by a digital controller as best shown in FIG. 10. The voltage from the terminals 107 of the conversion system of the present invention is applied to the load 113 through a digital storage of voltage data unit 108, a digital load control 109 and a cascade of switching transistors 110, 111 and 112. The controller functions to provide a lower resistance at a lower voltage, and a higher resistance at a higher voltage, or a higher current at a lower voltage and a lower current at a higher voltage so as to improve the heat transfer as explained above.

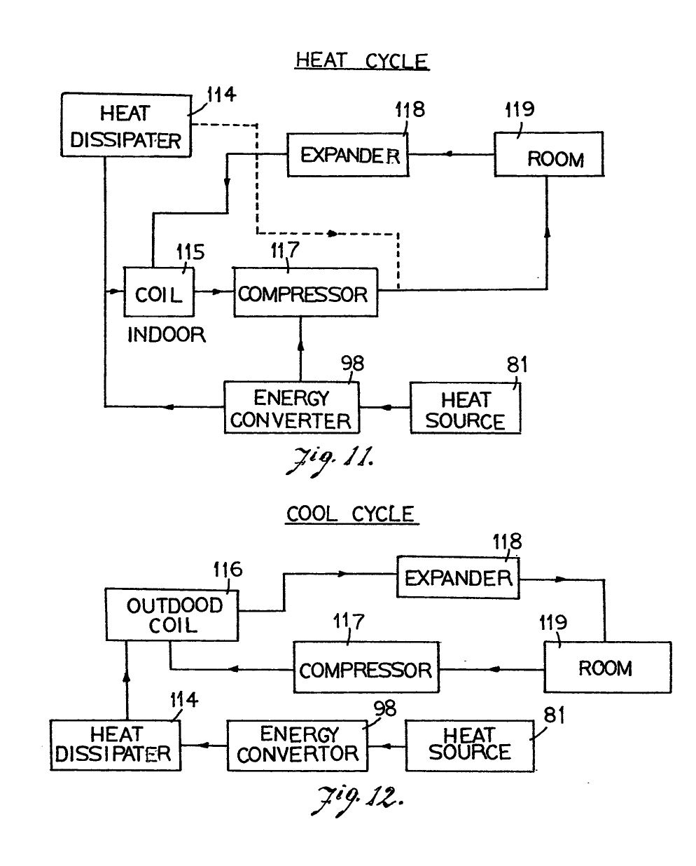

The conversion system of the present invention may be used in a heating and cooling system as illustrated in FIGS. 11 and 12. The main power for the heating or cooling is provided by the heat source 81. The heat from the heat source 81 is applied to the conversion system 98 of the present invention. The heat is dissipated or used by the heat dissipater 114 which can be an indoor dissipater in conjunction with the heat exchange coil 115 in the winter or an outdoor dissipater in conjunction with an outdoor coil 116 in the summer. The system derives its power to run the compressor 117 from the conversion system 98, and the heating and cooling is provided by a low boiling fluid in the expander 118 to heat or cool the room 119.

Without further analysis, the foregoing will so fully reveal the gist of the present invention that others can, by applying the disclosed knowledge, readily adapt it for various applications without omitting features that, from the stand point of prior art, fairly constitute essential characteristics of the generic and specific aspects of my contribution to the art and, therefore, such adaptation should and are intended to be comprehended within the meaning and scope of equivalence of the appended claims.

1. A heat energy conversion system comprising,
a transducer adapted to generate a basic voltage from a heat source,
an inverter charger operative for increasing said basic voltage to an operating voltage having a predetermined voltage level,
a charge storage means adapted for receiving said operating voltage from said inverter charger and for retaining said operating voltage therein,
a control means operative to regulate charging operation of said charge storage means for maintaining said charge storage means at a fully charge condition all the time,
a output means operative for delivering said operating voltage from said charge storage means to a load.

2. A heat energy conversion system according to claim 1 wherein said transducer is a thermoelectric module.

3. A heat energy conversion system according to claim 1 wherein said transducer is a thermopile, and said charge storage means is a super capacitor.

4. A heat energy conversion system according to claim 3 wherein said heat source is a burner flame generated by a pilot burner of a heating furnace.

5. A heat energy conversion system according to claim 4 including a regulation means operating with said control means for actuating said pilot burner to turn on said flame selectively in predetermined time intervals for maintaining said super capacitor fully charged and in an event when additional voltage is required by said load.

6. A heat energy conversion system according to claim 5 wherein said regulation means is connected to a spark generator unit of said heating furnace and operative to actuate said spark generator unit to turn on said pilot burner to generate said flame.

7. A heat energy conversion system according to claim 6 including a potentiometer in conjunction with two series resistor connected to said regulator means, operative for varying the voltage level of said operating voltage for charging said super capacitor in said time intervals.

8. A heat energy conversion system according to claim 7 including a control circuit means connected to said regulation means and a main control valve for controlling actuation of a main burner control valve of said heating furnace and operative for actuating said main burner control valve by said operating voltage after said pilot burner has been actuated for a predetermined period of time.

9. A heat energy conversion system comprising,
a thermopile located on an inner surface of a vertical heat conducting flue wall of a heating, cooling and venting equipment, said thermopile being operative for generating a basic voltage when said flue wall is heated,
a pilot burner located in said equipment adapted to generate a pilot flame for heating an outer surface of said flue wall,
an inverter charger operative for increasing said basic voltage to an operating voltage having a predetermined voltage level,
a super capacitor coupled to said inverter charger and adapted to be charge by said inverter charger to store said operating voltage therein,
a regulator means coupled to said super capacitor and operative to maintain said super capacitor fully charged,
a pilot control valve coupled to said regulator means and operative to actuated said pilot burner to generate said pilot flame selectively in predetermined time intervals and at occasion when said operating voltage is required by a load.

10. A heat energy conversion system according to claim 9 including a heat exchanger attached to said thermopile, an air circulation means operative by said operating voltage from said super capacitor for circulating air through said heat exchanger to extract heat therefrom to a room to be heated.

11. A heat energy conversion system according to claim 9 including a heat pipe connected to said flue wall and a heat conducting member operative to be heated by an external heat source.

12. A heat energy conversion system according to claim 11 wherein said external heat source is provided selectively by an wood fire, solar heat, hot spring, volcanic pool.

13. A heat energy conversion system according to claim 12 including a fluid pressure vessel adapted to receive heat from said heat source, a fluid having a low boiling point located in said fluid pressure vessel and operative to generate a vapor pressure, a turbine coupled to said pressure vessel and operative to be driven by said vapor pressure to provide a mechanical motion output.

14. A heat energy conversion system according to claim 13 wherein said mechanical motion output is used to operate said air circulating means.
